(19) United States
(12) Patent Application Publication
(10) Pub. No.: US 2003/0115747 A1
(43) Pub. Date: Jun. 26, 2003

(54) Pick-up tool for mounting semiconductor chips

(75) Inventors: Daniel Schnetzler, Unterageri (CH); Guido Heggli, Cham (CH); Rolf Huwyler, Bremgarten (CH)

Correspondence Address: DAVID B. RITCHIE, THELEN REID & PRIEST LLP, P.O. BOX 640640, SAN JOSE, CA, 95164-0640, US

(73) Assignee: ESEC Trading SA, a Swiss Corporation

(21) Appl. No.: 10/327,493

(22) Filed: Dec. 20, 2002

(30) Foreign Application Priority Data
Dec. 21, 2001 (CH) 2001 2337/01

(51) Int. Cl. H05K 3/36; B23P 19/00; A47J 45/00

(52) U.S. Cl. 29/830; 29/832; 29/743; 294/64.1

(57) ABSTRACT

With a pick-up tool with a suction organ made of elastically deformable material, a surface for picking the semiconductor chip is formed convex. On placing the semiconductor chip onto an already mounted semiconductor chip the centre of the semiconductor chip impacts first. The convex surface is increasingly deformed as a result of the pressure build-up until it and the picked semiconductor chip are flat. The pressure builds up from the centre of the suction organ outwards. In doing so, the semiconductor chip is rolled onto the lower semiconductor chip, whereby the air can continuously escape.

### PRIORITY CLAIM

The present application claims priority under 35 U.S.C §119 based upon Swiss Patent Application No. 2001 2337/01 filed on Dec. 21, 2001.

### FIELD OF THE INVENTION

The invention concerns a pick-up tool for mounting semiconductor chips. Such pick-up tools are also known under the terms “die collet” or “die bonding tool”.

### BACKGROUND OF THE INVENTION

With the mounting of semiconductor chips, the semiconductor chips sawn out of a wafer and attached to a foil are picked by the pick-up tool and placed onto a substrate. Such a pick-up tool basically comprises a metal shaft and a suction organ attached to it. The suction organ has a cavity directed towards the semiconductor chip to be picked to which vacuum can be applied via a drill hole. As soon as the suction organ rests on the semiconductor chip, the vacuum causes the semiconductor chip to adhere to the suction organ. In the trade, the suction organ is called a pick-up tool or rubber tip.

Semiconductor chips are also mounted on top of each other, in the trade the chips which are mounted on top of each other are known as “stacked dies”. Here, a first semiconductor chip is firstly mounted onto a substrate, as a rule in a conventional way by means of a portion of adhesive made from epoxy. The attachment of a second semiconductor chip onto the first semiconductor chip takes place by means of an adhesive film applied to the back of the second semiconductor chip. Here, the back of a wafer with the second semiconductor chips is coated with the adhesive, the wafer is then glued onto a foil and sawn into the individual second semiconductor chips. Afterwards, the semiconductor chips are picked by a Pick and Place system and, under the application of pressure at temperatures in the range of around 100-150° C., laminated onto the first semiconductor chip. This mounting process is known in the trade under the name of “precoated chip process” or “film bonding”. The advantages of this process lie in that the adhesive film has a uniform thickness so that the mounted semiconductor chips demonstrate no tilt. In addition, the adhesive coating spreads over the entire back of the second semiconductor chip so that there is no danger of voids and without a fillet of adhesive encircling the second semiconductor chip. This enables connection areas (pads) for the bond wires which are to connect the two semiconductor chips to be provided on the first semiconductor chip immediately adjacent to the edge of the second semiconductor chip.

In order to avoid even the smallest damage to the semiconductor chip on mounting, pick-up tools are used the suction organ of which is made of rubber. Rubber has the additional advantage that it seals the hollow chamber so well that the semiconductor chip can be detached from the foil with a relatively large suction force.

In order to save space, the semiconductor chips are made increasingly thin. With a thickness of around 150 um however, it can happen that the semiconductor chip picked by the pick-up tool bends because the semiconductor chip is pressed against the suction opening by the pressure created by the vacuum. With a thickness of 100 μm this is practically without exception. On placing the semiconductor chip onto the lower semiconductor chip undesired air bubbles form underneath the second semiconductor chip because the bent chip first comes to rest with its edges on the first semiconductor chip and the cavity formed between the two semiconductor chips is sealed so that the trapped air can no longer escape.

### BRIEF DESCRIPTION OF THE INVENTION

The object of the invention is to develop a pick-up tool which enables the mounting of thin semiconductor chips without any difficulties.

A pick-up tool according to the invention has a suction organ made of elastically deformable material the surface of which for picking the semiconductor chip is convex. For the supply of vacuum, the surface of the suction organ for picking the semiconductor chip has, for example, openings arranged in the area of its edges to which vacuum can be applied while the centre of this surface has no openings. Alternatively, the suction organ has at least one cavity filled with porous material over which the vacuum is fed to the convex surface. On placing the semiconductor chip onto an already mounted semiconductor chip, the convex surface is increasingly deformed as a result of the increasing pressure until it and the picked semiconductor chip are flat. The pressure builds up from the centre of the suction organ outwards. In doing so, the semiconductor chip is rolled onto the lower semiconductor chip whereby the air can continuously escape.

With this mounting process, the semiconductor chip picked by the suction organ is therefore brought into a convex shape before being placed onto the already mounted semiconductor chip and is then returned to its normal shape during the last phase of placement.

In the following, embodiments of the invention are explained in more detail based on the drawing. The figures are not presented to scale but in such a way that the nature of the invention is expressed illustratively.

### BRIEF DESCRIPTION OF THE DRAWING FIGURES

In the drawings:

FIG. 1 shows a lateral cross-section of a pick-up tool with a suction organ with a convex surface which serves the mounting of a semiconductor chip,

FIGS. 2A, B show a plan view of the convex surface,

FIG. 3 shows a lateral cross-section of a second pickup tool,

FIG. 4A shows a lateral cross-section of a third pick-up tool,

FIG. 4B shows a plan view of the convex surface of the third pick-up tool, and

FIGS. 5, 6 show snapshots during the mounting process.

### DETAILED DESCRIPTION OF THE INVENTION

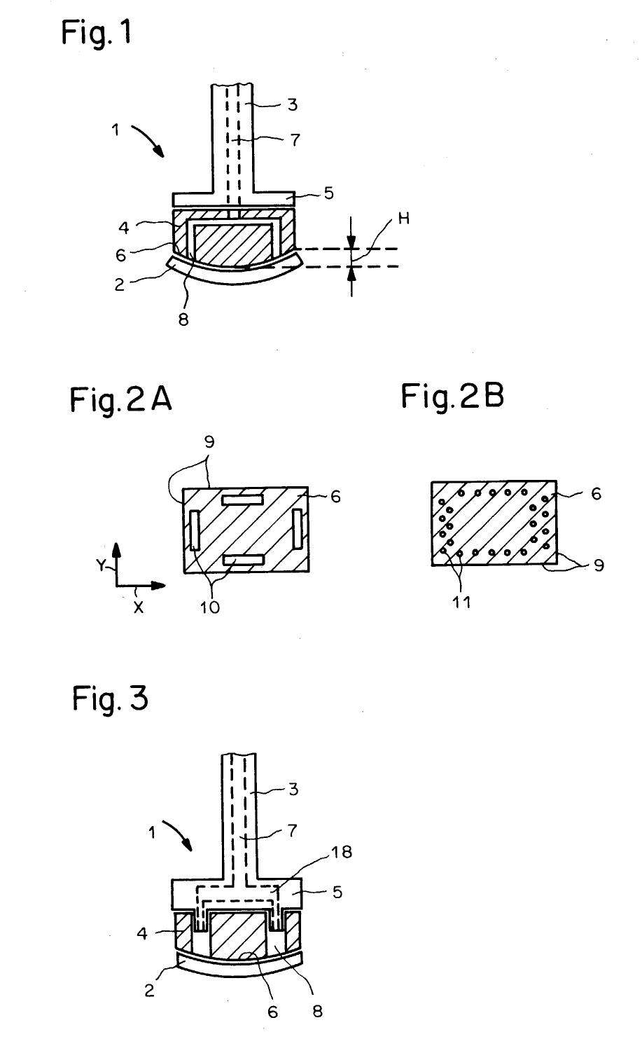

FIG. 1 shows a lateral cross-section of a pick-up tool 1 that has picked a semiconductor chip 2. The pick-up tool 1 comprises a shaft 3 and a suction organ 4, made out of elastically deformable material such as rubber, secured in the shaft 3. A plate 5 made out of a dimensionally stable material is attached to the lower end of the shaft 3. As a rule, the shaft 3 and plate 5 are formed as one piece. The plate 5 supports the suction organ 4 in order to transfer the pressure, created by the shaft 3 on placing the semiconductor chip 2, over the entire suction organ 4 and to prevent the suction organ 4 from bending upwards in the direction of the plate 5. In accordance with the invention, the surface 6 of the suction organ 4 facing towards the semiconductor chip 2 is formed convex. The degree of convexity, ie, the height difference between the centre and the edge of the convex surface 6, is marked with the reference character H. The suction organ 4 holds the semiconductor chip 2 with vacuum that is fed to the convex surface 6 via a longitudinal drill hole 7 in the shaft 3. In the following, two embodiments are explained that differ in the way in which the vacuum is supplied.

### EXAMPLE 1

With this embodiment, the convex surface 6 of the suction organ 4 facing towards the semiconductor chip 2 has openings 8 to which vacuum can be supplied. The openings 8 are arranged close to the edge of the surface 6 while the centre of the surface 6 has no openings. FIG. 2A and FIG. 2B show a plan view of the surface 6. The openings 8 are, for example, parallel to the slits 10 running along the edges 9 of the suction organ 4 as is shown in FIG. 2A, or comprise numerous drill holes 11 arranged in the area of the edges 9 as is shown in FIG. 2B.

FIG. 2A also shows a Cartesian system of co-ordinates the axes of which are identified with x and y. The surface 6 is either formed convex in relation to one single direction, for example the x direction, or formed convex in relation to the x and the y direction.

FIG. 3 shows an embodiment of the pick-up tool 1 with which the vacuum channels 18 run as far as possible within the shaft 3 and the plate 5. In the suction organ 4 the vacuum channels 18 only run in vertical direction. In this way, the mechanical stability of the central area of the suction organ 4 is increased.

### EXAMPLE 2

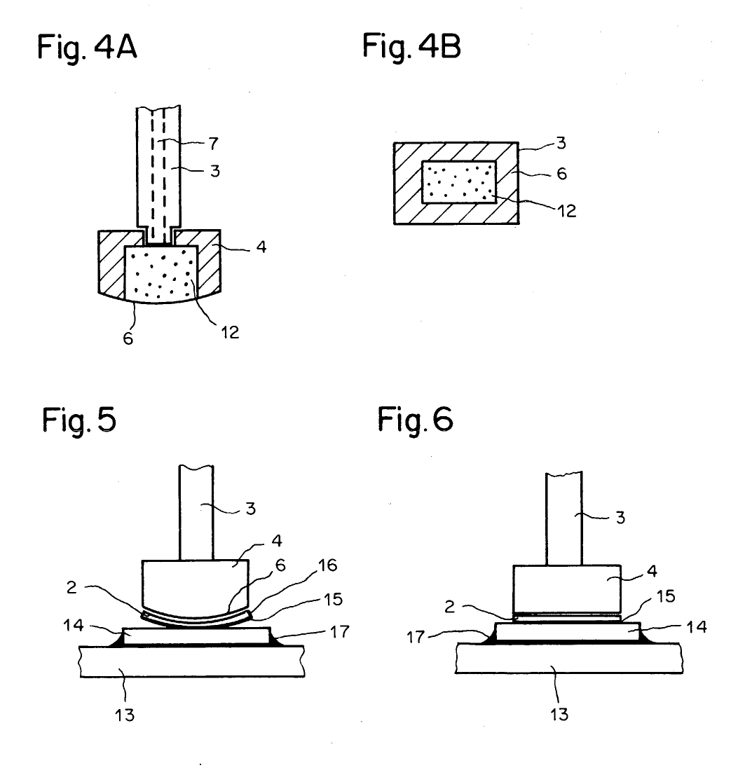

With this embodiment described based on FIGS. 4A and 4B, the suction organ 4 has a cavity 12 filled with a porous material to which vacuum is applied. The cavity 12 is located, for example, in the centre of the surface 6 of the suction organ 4.

A further possibility exists in providing slits 10 and/or drill holes 11 in accordance with example 1 and to fill these with porous material.

FIGS. 5 and 6 each show a snapshot of the process of placing the semiconductor chip 2 onto a semiconductor chip 14 already mounted onto a substrate 13, whereby details of the pick-up tool 1 are not presented. An adhesive film 15 is glued to the back of the semiconductor chip 2. In the following, by semiconductor chip 2 is meant the semiconductor chip 2 together with the adhesive film 15 applied to its back. As a result of the vacuum prevailing in the openings 8 (FIG. 1), the semiconductor chip 2 has adapted itself to the curvature of the convex surface 6 of the suction organ 4. Consequently, the centre of the semiconductor chip 2 impacts first on the semiconductor chip 14. This condition is presented in FIG. 5. When the shaft 3 of the pick-up tool 1 is now lowered further, a pressure builds up that causes an increasing deformation of the suction organ 4 until the semiconductor chip 2 rests flat on the semiconductor chip 14. This condition is presented in FIG. 6. Thanks to the convex shape of the surface 6, the pressure builds up from the centre of the suction organ 4 outwards. In doing so, the semiconductor chip 2 is rolled onto the semiconductor chip 14 whereby the air can continuously escape. The edges 16 of the semiconductor chip 2 only impact on the semiconductor chip 14 at the end. In order that the adhesive film 15 can develop its adhesion, the substrate 13 is heated to the necessary temperature in the conventional way. While the semiconductor chip 14 is surrounded by a fillet 17 of adhesive in the customary manner, such a fillet is missing with the semiconductor chip 2.

The degree of convexity of the surface 6 of the suction organ 4 lies preferably in the order of half the thickness of the adhesive film 15. Therefore, with a thickness of the adhesive film 15 of 60 μm, the height difference H (FIG. 1) between the centre and the edge of the surface 6 amounts, for example, to around 30 um.

Because the convexity of the surface 6 is relatively small in comparison to its dimensions of typically 10 mm*10 mm, the plate 5 can be omitted when the suction organ 4 itself has, on the one hand, the necessary stiffness or hardness and, on the other hand, the necessary elasticity in order to bring the surface 6 from the unloaded, convex condition (FIG. 5) to the flat condition (FIG. 6) necessary on placing the semiconductor chip 2.

During the transitional phase from the condition shown in FIG. 5 where the semiconductor chip 2 impacts on the semiconductor chip 14 and the condition shown in FIG. 6 where the semiconductor chip 2 rests flat on the semiconductor chip 14, the lowering of the pick-up tool 1 can take place, for example, with constant speed or with a speed profile adapted to the desired curve of the pressure or force build-up.

While embodiments and applications of this invention have been shown and described, it would be apparent to those skilled in the art having the benefit of this disclosure that many more modifications than mentioned above are possible without departing from the inventive concepts herein. The invention, therefore, is not to be restricted except in the spirit of the appended claims and their equivalents.

What is claimed is:

1. A pick-up tool for mounting semiconductor chips, comprising
a shaft, and
a suction organ coupled to the shaft, the suction organ being made of elastically deformable material and comprising a surface for picking a semiconductor chip, said surface being formed convex.

2. The pick-up tool according to claim 1, wherein the surface of the suction organ for picking the semiconductor chip has openings arranged in the area of its edges to which vacuum can be applied, and wherein a centre of this surface has no openings.

3. The pick-up tool according to claim 2, wherein the openings are filled with porous material.

4. The pick-up tool according to claim 1, wherein the suction organ has at least one cavity filled with porous material to which vacuum can be applied.

5. The pick-up tool according to claim 1, wherein a plate that supports the suction organ is arranged at a lower end of the shaft.

6. The pick-up tool according to claim 2, wherein a plate that supports the suction organ is arranged at a lower end of the shaft.

7. The pick-up tool according to claim 3, wherein a plate that supports the suction organ is arranged at a lower end of the shaft.

8. The pick-up tool according to claim 4, wherein a plate that supports the suction organ is arranged at a lower end of the shaft.

9. A method for mounting a second semiconductor chip onto a first semiconductor chip, whereby a back of the second semiconductor chip is coated with an adhesive film, comprising the steps of:
deforming the second semiconductor chip into a convex shape;
placing the second semiconductor chip onto the first semiconductor chip; and
returning the second semiconductor chip to its normal shape during the final phase of placement.
